(19) United States
(12) Patent Application Publication
(10) Pub. No.: US 2025/0248078 A1
(43) Pub. Date: Jul. 31, 2025

(54) SEMICONDUCTOR DEVICE

(71) Applicant: DENSO CORPORATION, Kariya-city (JP)

(72) Inventors: Hiroto SUGIURA, Kariya-city (JP); Masanori MIYATA, Kariya-city (JP); Jun OKAWARA, Kariya-city (JP)

(21) Appl. No.: 19/182,461

(22) Filed: Apr. 17, 2025

Related U.S. Application Data
(63) Continuation of application No. PCT/JP2023/035323, filed on Sep. 28, 2023.

(30) Foreign Application Priority Data
Oct. 27, 2022 (JP) 2022-172331

(51) Int. Cl. H10D 62/10; H10D 12/00; H10D 62/17

(52) U.S. Cl. CPC H10D 62/105; H10D 12/481; H10D 62/393; H10D 62/126

(57) ABSTRACT

A semiconductor device includes a semiconductor substrate that includes a drift layer of a first conductivity type, a collector layer of the second conductivity type, and a field stop layer of the first conductivity type disposed between the collector layer and the drift layer. The collector layer has a total dose of less than 1×10¹³/cm². The collector layer has a plurality of peaks of a carrier concentration. At least a portion of the collector layer is configured to satisfy a condition that a dose contained within ±3σp of a deepest peak, which is a peak at a deepest position relative to a rear surface of the semiconductor substrate among the plurality of peaks, accounts for 13% or more of the total dose.

### CROSS REFERENCE TO RELATED APPLICATIONS

The present application is a continuation application of International Patent Application No. PCT/JP2023/035323 filed on Sep. 28, 2023, which designated the U.S. and claims the benefit of priority from Japanese Patent Application No. 2022-172331 filed on Oct. 27, 2022. The entire disclosures of all of the above applications are incorporated herein by reference.

### TECHNICAL FIELD

The present disclosure relates to a semiconductor device.

### BACKGROUND

JP 2020-43301 A (corresponding to US 2021/0217845 A1) discloses a semiconductor device in which an insulated gate bipolar transistor (IGBT) is formed as a vertical element. The disclosure of JP 2020-43301 A is incorporated herein by reference as an explanation of technical elements in the present disclosure.

### SUMMARY

The present disclosure provides a semiconductor device including a drift layer of a first conductivity type, a base layer of a second conductivity type disposed on the drift layer and providing a front surface of a semiconductor substrate, an emitter region of the first conductivity type disposed in a surface layer of the base layer close to the front surface, a gate electrode facing the base layer located between the drift layer and the emitter region through a gate insulating film, a collector layer of the second conductivity type disposed on an opposite side of the drift layer from the base layer and providing a rear surface of the semiconductor substrate, a field stop layer of the first conductivity type disposed between the collector layer and the drift layer and having a carrier concentration higher than a carrier concentration of the drift layer, an emitter electrode disposed on the front surface and electrically connected to the base layer and the emitter region, and a collector electrode disposed on the rear surface and electrically connected to the collector layer. The collector layer has a total dose of less than 1×10¹³/cm². The collector layer has a plurality of peaks of a carrier concentration. At least a portion of the collector layer is configured to satisfy a condition that a dose contained within ±3σp of a deepest peak, which is a peak at a deepest position relative to the rear surface among the plurality of peaks, accounts for 13% or more of the total dose.

### BRIEF DESCRIPTION OF DRAWINGS

Objects, features and advantages of the present disclosure will become apparent from the following detailed description made with reference to the accompanying drawings. In the drawings:

FIG. 1 is a diagram showing a semiconductor device according to a first embodiment;

FIG. 2 is a cross-sectional view of the semiconductor device taken along line II-II of FIG. 1;

FIG. 3 is a timing chart showing an operation of the semiconductor device;

FIG. 4 illustrates the electric field strength of a semiconductor device;

FIG. 5 is a diagram for explaining an electric field strength peak when a short circuit occurs;

FIG. 6 is a diagram showing a plurality of peaks of carrier concentration in a collector layer;

FIG. 7 is a diagram showing a relationship between a dose at a deepest peak and a short circuit capacity improvement rate;

FIG. 8 is a diagram showing a relationship between an on-voltage and a turn-off loss;

FIG. 9 is a diagram showing a semiconductor device according to a second embodiment;

FIG. 10 is a diagram showing a first element region;

FIG. 11 is a diagram showing a second element region;

FIG. 12 is a cross-sectional view of a part of a semiconductor device according to a modified example;

FIG. 13 is a cross-sectional view of a part of a semiconductor device according to another modified example; and

FIG. 14 is a cross-sectional view of a part of a semiconductor device according to another modified example.

### DETAILED DESCRIPTION

Next, a relevant technology is described only for understanding the following embodiments. In a semiconductor device having a vertical IGBT formed therein, a breakdown voltage can be improved by disposing a field stop layer of n⁺-type between a drift layer of n⁻-type and a collector layer of p⁺-type. In addition, a short circuit capacity can be improved by setting a distance between maximum peaks of carrier concentrations in the field stop layer and the collector layer and a ratio of a total dose of the collector layer to a total dose of the field stop layer so as to satisfy a specific relationship.

However, in applications requiring low turn-off loss, the total dose of the collector layer must be reduced, and the above-described distance and the above-described ratio of the total dose may not satisfy the specific relationship. That is, there is a possibility that short circuit capacity cannot be ensured. From the above-described viewpoint or from other viewpoints not mentioned, further improvement is required for the semiconductor device.

A semiconductor device according to an aspect of the present disclosure includes a drift layer of a first conductivity type, a base layer of a second conductivity type disposed on the drift layer and providing a front surface of a semiconductor substrate, an emitter region of the first conductivity type disposed in a surface layer of the base layer close to the front surface, a gate electrode facing the base layer located between the drift layer and the emitter region through a gate insulating film, a collector layer of the second conductivity type disposed on an opposite side of the drift layer from the base layer and providing a rear surface of the semiconductor substrate, a field stop layer of the first conductivity type disposed between the collector layer and the drift layer and having a carrier concentration higher than a carrier concentration of the drift layer, an emitter electrode disposed on the front surface and electrically connected to the base layer and the emitter region, and a collector electrode disposed on the rear surface and electrically connected to the collector layer. The collector layer has a total dose of less than 1×10¹³/cm². The collector layer has a plurality of peaks of a carrier concentration. At least a portion of the collector layer is configured to satisfy a condition that a dose contained within ±3σp of a deepest peak, which is a peak at a deepest position relative to the rear surface among the plurality of peaks, accounts for 13% or more of the total dose.

According to the semiconductor device described above, the total dose in the collector layer is less than 1×10¹³/cm², so that a turn-off loss can be reduced. In addition, at least the portion of the collector layer is provided such that the dose contained within +3σp of the deepest peak among the plurality of peaks accounts for 13% or more of the total dose. This makes it possible to improve a short circuit capacity. Accordingly, the semiconductor device can reduce the turn-off loss while improving the short circuit capacity.

A plurality of aspects disclosed in the present specification employ technical means different from one another for achieving respective objectives.

Hereinafter, multiple embodiments will be described with reference to the drawings. The same reference numerals are assigned to corresponding elements in each embodiment, and thus, duplicate descriptions may be omitted. When only part of the configuration is described in each embodiment, the configuration of the other preceding embodiments can be applied to other parts of the configuration. Further, not only the combinations of the configurations explicitly shown in the description of the respective embodiments, but also the configurations of the plurality of embodiments can be partially combined even when they are not explicitly shown as long as there is no difficulty in the combination in particular.

Semiconductor devices according to the present embodiment are applicable to, for example, a power conversion device for a moving object with a rotary electric machine as a drive source. The movable object is, for example, an electrically driven vehicle such as an electric vehicle (BEV), a hybrid vehicle (HEV), or a plug-in hybrid vehicle (PHEV), a flying object, a ship, a construction machine, or an agricultural machine. The flying object may be, for example, an electric vertical takeoff and landing aircraft or a drone.

### First Embodiment

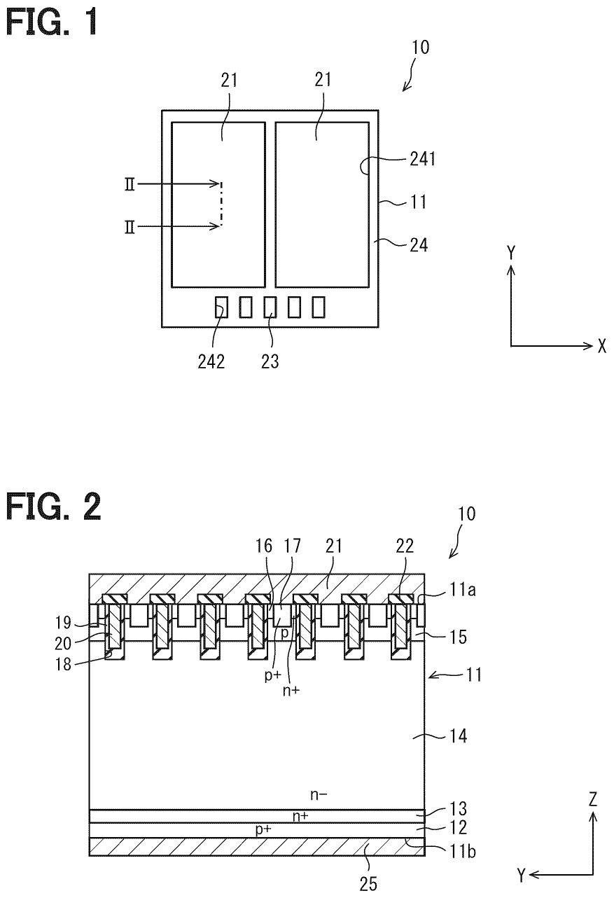

First, a schematic configuration of a semiconductor device 10 will be described with reference to FIG. 1 and FIG. 2. FIG. 1 is a top plan view of the semiconductor device 10. FIG. 2 is a cross-sectional view of the semiconductor device 10 taken along line II-II of FIG. 1. As an example, the semiconductor device 10 of the present embodiment is applied to a direct current to direct current (DC-DC) converter.

### <Semiconductor Device>

Hereinafter, a thickness direction of the semiconductor substrate is defined as a Z direction. A direction perpendicular to the Z direction is defined as an X direction. A direction orthogonal to both the Z direction and the X direction is defined as a Y direction. Unless otherwise specified, a shape viewed in a plane from the Z direction, that is, a shape along an XY plane defined by the X direction and Y direction is referred to as a planar shape. Furthermore, a plan view from the Z direction may simply be referred to as plan view.

As shown in FIG. 1 and FIG. 2, a semiconductor device 10 includes a semiconductor substrate 11. The semiconductor substrate 11 is made of silicon (Si), a wide bandgap semiconductor having a wider bandgap than silicon, or the like. Examples of wide bandgap semiconductors include silicon carbide (SiC), gallium nitride (GaN), gallium oxide (Ga₂O₃) and diamond.

A vertical element is formed on the semiconductor substrate 11. The vertical element is configured to pass a main current in a thickness direction of the semiconductor substrate 11, that is, in the Z direction. The vertical element is an IGBT. IGBT is an abbreviation for Insulated Gate Bipolar Transistor. The semiconductor substrate 11 has a front surface 11a and a rear surface 11b, which are plate surfaces on which electrodes are disposed.

The semiconductor substrate 11 has a collector layer 12, a field stop layer 13 (hereinafter, FS layer 13), a drift layer 14, a base layer 15, an emitter region 16, and a base contact region 17. The semiconductor substrate 11 has semiconductor regions formed thereon by ion implantation of impurities or the like. The semiconductor regions of the semiconductor substrate 11 may be referred to as semiconductor layers, diffusion layers, or the like.

The collector layer 12 is disposed on an opposite side of the drift layer 14 from the base layer 15. The collector layer 12 is formed in a surface layer close to the rear surface 11b of the semiconductor substrate 11. The collector layer 12 provides the rear surface 11b of the semiconductor substrate 11. The collector layer 12 is a semiconductor region of p-conductivity type (p+) having a higher impurity concentration than the base layer 15.

The FS layer 13 is disposed between the collector layer 12 and the drift layer 14. The FS layer 13 is formed on a surface of the collector layer 12 opposite the rear surface 11b. The FS layer 13 is a semiconductor region of n-conductivity type (n+) having a higher carrier concentration (impurity concentration) than the drift layer 14. By providing the FS layer 13, a depletion layer can be restricted from expanding toward the collector layer 12. The FS layer 13 may be referred to as a buffer layer.

The drift layer 14 is disposed between the FS layer 13 and the base layer 15. The drift layer 14 is formed on a surface of the FS layer 13 opposite to the surface close to the collector layer 12. The drift layer 14 is a semiconductor region of n-conductivity type (n−) having a lower impurity concentration than the FS layer 13.

The base layer 15 is disposed on a surface of the drift layer 14 opposite to the surface close to the FS layer 13. The base layer 15 is formed in a surface layer of the semiconductor substrate 11 close to the front surface 11a. The base layer 15 provides the front surface 11a of the semiconductor substrate 11. The base layer 15 is a semiconductor region of p-type conductivity (p) having a lower impurity concentration than the collector layer 12. The base layer 15 may be referred to as a channel region, a body region, or the like.

The emitter region 16 is disposed in a surface layer of the base layer 15 close to the front surface 11a. The emitter region 16 terminates within the base layer 15. The emitter region 16 is a semiconductor region of n-conductivity type (n+) having a higher carrier concentration than the drift layer 14. The emitter region 16 is formed so as to be in contact with a side surface of each trench 18 which will be described later. The emitter region 16 extends along an extension direction of the trenches 18.

Similar to the emitter region 16, the base contact region 17 is disposed in the surface layer of the base layer 15 close to the front surface 11a. The base contact region 17 terminates within the base layer 15. The base contact region 17 is a semiconductor region of p-conductivity type (p+) having a higher impurity concentration than the base layer 15. The base contact region 17 is disposed adjacent to the emitter region 16. The base contact region 17 also extends along the extension direction of the trenches 18. As an example, the base contact region 17 in the present embodiment is formed to a position deeper than the emitter region 16. The base contact region 17 may be referred to as a body contact region, a contact region, or the like.

The semiconductor substrate 11 having the above-described configuration has the plurality of trenches 18. The trenches 18 are formed to a predetermined depth from the front surface 11a. The trenches 18 penetrate the base layer 15. Tip ends of the trenches 18 reach the drift layer 14. As an example, each of the trenches 18 in the present embodiment extends in the X direction. The trenches 18 are arranged at substantially equal intervals in the Y direction, and form a stripe shape in plan view. The trenches 18 define cells. The cells may be referred to as main cells, unit structural parts, unit circuits, elements, or the like. A plurality of cells are connected in parallel to each other to form the IGBT with a trench gate structure.

A gate insulating film 19 is formed on a wall surface of each of the trenches 18. The gate insulating film 19 is made of an oxide film or the like, and is formed so as to cover the wall surface of each of the trenches 18. A gate electrode 20 is formed on a surface of the gate insulating film 19 to embed each of the trenches 18. The gate electrode 20 is made of doped polysilicon or the like. Each of the trenches 18 is filled with the gate insulating film 19 and the gate electrode 20.

The gate electrode 20 penetrates through the base layer 15 and reaches the drift layer 14. The semiconductor substrate 11 has the plurality of gate electrodes 20. Each of the gate electrodes 20 extends in the X direction. The gate electrodes 20 are arranged at substantially equal intervals in the Y direction and have a stripe shape in plan view.

An emitter electrode 21 is disposed on the front surface 11a of the semiconductor substrate 11. The emitter electrode 21 is electrically connected to the emitter region 16. The emitter electrode 21 is electrically connected to the base layer 15 via the base contact region 17. The emitter electrode 21 is electrically isolated from the gate electrodes 20 by an interlayer insulating film 22 such as BPSG. BPSG is an abbreviation for boron phosphosilicate glass.

On the front surface 11a of the semiconductor substrate 11, pads 23 serving as signal electrodes are also disposed. The pads 23 are formed at positions that do not overlap the emitter electrode 21 in plan view, specifically, in an outer periphery region that surrounds an element formation region. The pads 23 include at least a pad for the gate electrodes 20. In the present embodiment, as an example, five pads 23 are formed on the semiconductor substrate 11. The five pads 23 are collectively formed on one end side in the Y direction in the semiconductor substrate 11 having a substantially rectangular planar shape, and are formed side by side in the X direction.

A protective film 24 is disposed on the front surface 11a of the semiconductor substrate 11. The protective film 24 is an insulating film provided on the front surface 11a of the semiconductor substrate 11 so as to cover a peripheral portion of the emitter electrode 21. The protective film 24 is made of, for example, polyimide or silicon nitride. The protective film 24 has opening portions 241 which define bonding regions of the emitter electrode 21 and opening portions 242 which define bonding regions of the pads 23.

A collector electrode 25 is disposed on the rear surface 11b of the semiconductor substrate 11. The collector electrode 25 is formed over almost the entire rear surface 11b. The collector electrode 25 is electrically connected to the collector layer 12.

In the semiconductor device 10 configured as described above, n-conductivity type corresponds to a first conductivity type, and p-conductivity type corresponds to a second conductivity type.

### <Operation of Semiconductor Device>

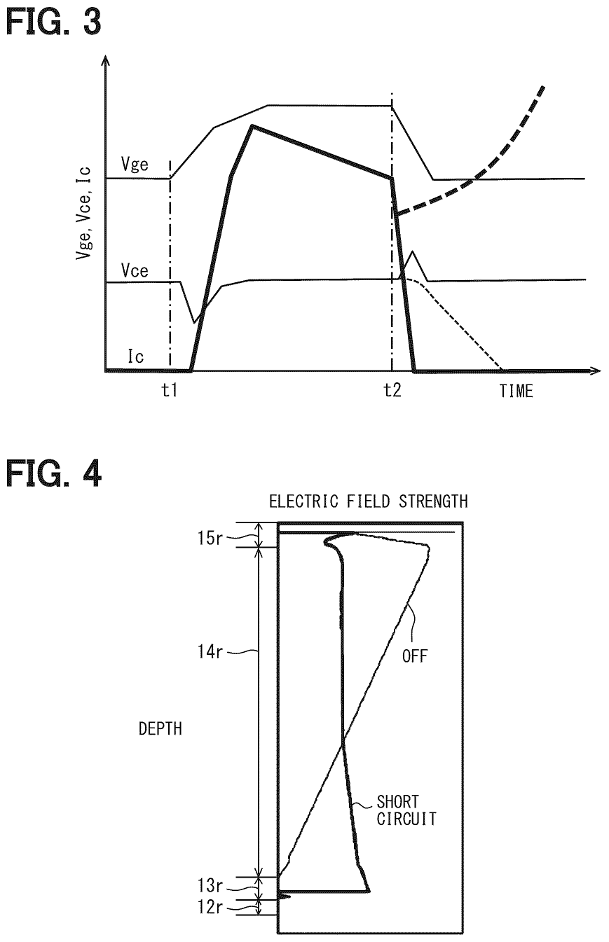

Next, the operation of the semiconductor device 10 (IGBT) will be described with reference to FIG. 3. FIG. 3 is a timing chart showing the operation of the semiconductor device 10.

When a voltage higher than that of the emitter electrode 21 is applied to the collector electrode 25, a pn junction formed between the base layer 15 and the drift layer 14 is brought into a reverse conductive state to form a depletion layer. In order to bring the IGBT into an ON state, a voltage equal to or higher than a threshold voltage Vth of the insulated gate structure is applied to the gate electrodes 20 while the voltage higher than that of the emitter electrode 21 is applied to the collector electrode 25. In FIG. 3, a voltage equal to or higher than the threshold voltage Vth is applied to the gate electrodes 20 at time t1.

This causes a gate-emitter voltage Vge to rise, and inversion layers, that is, channels, are formed in portions of the base layer 15 that contact the trenches 18. Then, electrons are supplied from the emitter region 16 to the drift layer 14 via the inversion layers, and electrons are supplied from the collector layer 12 to the drift layer 14, so that a resistance value of the drift layer 14 decreases due to conductivity modulation, and the IGBT is brought into the ON state. That is, the collector-emitter voltage Vce drops and the current Ic flows.

Then, when the application of voltage to the gate electrodes 20 is stopped at time t2, the gate-emitter voltage Vge drops, the inversion layers disappear, and the IGBT is brought into an OFF state. That is, the current Ic decreases and the IGBT is brought into the OFF state. However, when a short circuit occurs, the current Ic increases sharply as shown by the dashed line in FIG. 3, while the collector-emitter voltage Vce drops sharply.

<Electric Field Strength during Short Circuit>

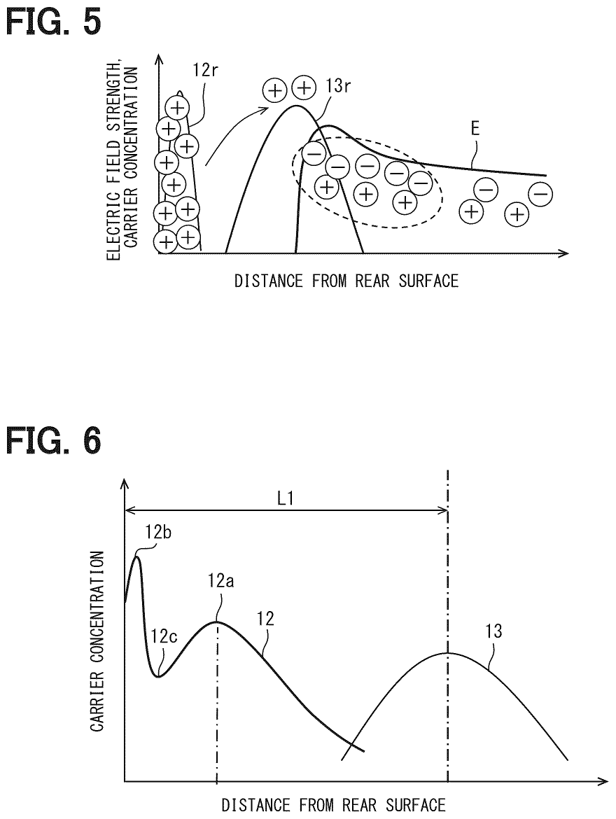

Next, an electric field strength when a short circuit occurs will be described with reference to FIG. 4 and FIG. 5. FIG. 4 shows a simulation result of a reference example. FIG. 5 is a diagram for explaining the occurrence of a peak of the electric field strength within an FS layer in the reference example. In FIG. 5, holes are indicated by + (plus) and electrons are indicated by − (minus).

In the reference example, reference numerals for respective elements are those of corresponding elements of the semiconductor device 10 with an “r” added to the end. In the reference example, a total dose of a collector layer 12r was set to 3.56×10¹²/cm². Moreover, the collector layer 12r was formed by one ion implantation and had a peak of carrier concentration at a shallow position, that is, at a position close to rear surface 11b, as shown in FIG. 5, in order to improve ohmic characteristics.

As shown in FIG. 4, in the reference example, the electric field strength when off had a peak near a junction of the base layer 15r and the drift layer 14r, and gradually decreased toward the collector layer 12r. On the other hand, the electric field strength when a short circuit occurred had a peak in the FS layer 13r.

In this way, when a short circuit occurred, the peak of the electric field strength occurred within the FS layer 13r because, as shown in FIG. 5, there were fewer holes injected at an end portion of the electric field strength (E) on a rear surface side of the substrate, resulting in an excess state of electrons at the end portion enclosed by the dashed line. When the peak of the electric field strength occurs on the rear surface side of the substrate in this manner, there is a possibility that avalanche breakdown will occur near the peak. That is, in a configuration including the FS layer 13r, there is a possibility that the short circuit capacity will be reduced.

By increasing the carrier concentration of the collector layer 12r, the number of holes injected into a position where the peak of the electric field strength in the FS layer 13r can occur increase, thereby making it possible to alleviate the above-described excess state of electrons. In other words, it is possible to restrict the occurrence of a peak in the electric field strength in the FS layer 13r when a short circuit occurs.

### <Collector Layer>

Next, the configuration of the collector layer 12 of the semiconductor device 10 will be mainly described with reference to FIG. 6. FIG. 6 is a diagram showing peaks of carrier concentrations in the collector layer 12 and the FS layer 13. FIG. 6 shows a distance from the rear surface 11b of the semiconductor substrate 11 to positions of the peaks of the carrier concentrations. When indicating the position of a peak, the apex of the peak is used as the reference.

The semiconductor device 10 of the present embodiment is applied to the DC-DC converter as described above. In order to meet the low turn-off loss required for the converter, the total dose of the collector layer 12 is less than 1×10¹³/cm². By reducing the total dose in this manner, the injection of holes at the time of turn-off can be suppressed, and the turn-off loss can be reduced. Therefore, for applications requiring low turn-off loss characteristics, it is difficult to improve the short circuit capacity by increasing the carrier concentration in the collector layer, as described above.

Therefore, in the present embodiment, as shown in FIG. 6, the carrier concentration in the collector layer 12 has a plurality of peaks. Some of the plurality of peaks may not be complete peaks, but may be in the form of gentle shoulders. As an example, the collector layer 12 has two peaks 12a and 12b. Among the plurality of peaks, the peak 12a is a peak located deepest from the rear surface 11b, that is, a deepest peak. Among the plurality of peaks, the peak 12a is a peak located closest to the FS layer 13. The peak 12b is a peak located closest to rear surface 11b, that is, a shallowest peak. The peak 12b is a peak located farthest from the FS layer 13.

At least a portion of the collector layer 12 is configured to satisfy a condition that a dose contained within ±3σp of a deepest peak, which is a peak at the deepest position relative to the rear surface 11b as a reference, accounts for 13% or more of the total dose. As an example, in the present embodiment, the dose contained within ±3σp of the peak 12a, which is the deepest peak, accounts for 13% or more of the total dose over the entire collector layer 12 in the element formation region.

Furthermore, the collector layer 12 is formed so that a minimum carrier concentration from the rear surface 11b to the deepest peak is 1×10¹⁶/cm³ or more. As an example, in the present embodiment, the carrier concentration is the lowest at a minimum concentration position 12c between the peaks 12a and 12b. A concentration at the minimum concentration position 12c where the carrier concentration is the lowest from the rear surface 11b to the peak 12a, which is the deepest peak, is 1×10¹⁶/cm³ or more.

The carrier concentration of the FS layer 13 also has at least one peak. In the example shown in FIG. 6, there is one peak. When a distance from the rear surface 11b to a maximum peak where the carrier concentration in the FS layer 13 is the maximum is defined as L1, the distance L1 is 0.8 μm or more. The distance L1 is the distance to the apex position of the maximum peak.

### <Summary of First Embodiment>

As described above, in the present embodiment, the total dose of the collector layer 12 is less than 1×10¹³/cm². By reducing the total dose in this manner, the injection of holes at the time of turn-off can be suppressed, and the turn-off loss can be reduced.

In addition, at least a portion of the collector layer 12 is provided so that the dose contained within ±3σp of the deepest peak (peak 12a) among the plurality of peaks of the carrier concentration accounts for 13% or more of the total dose. In this way, by ensuring the dose around the deepest peak, it is possible to improve the short circuit capacity while reducing the total dose. As described above, the semiconductor device 10 of the present embodiment can reduce the turn-off loss while improving the short circuit capacity. The semiconductor device 10 is suitable for applications requiring low turn-off characteristics, such as converters. In the present embodiment, the collector layer 12 satisfies both of the above conditions over the entire element formation region.

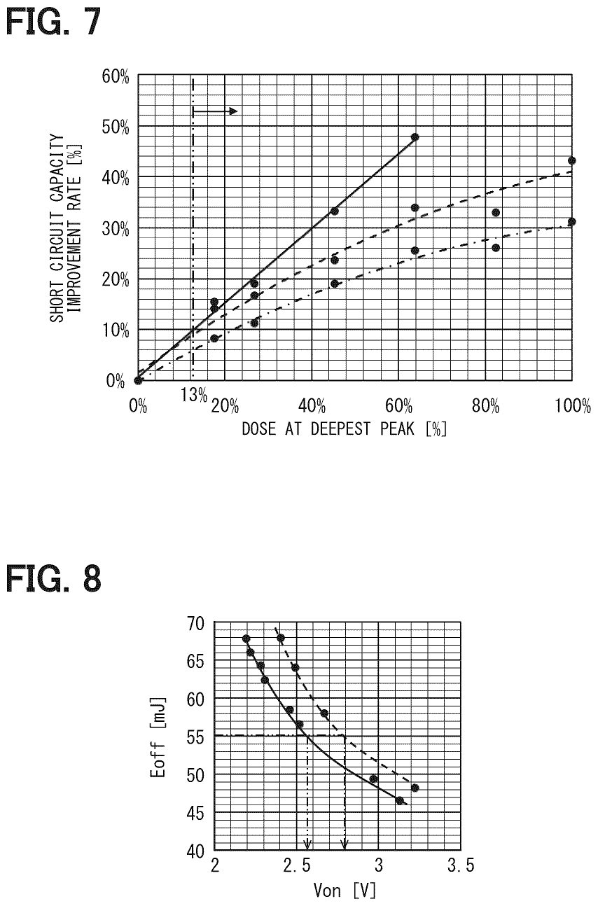

FIG. 7 is a diagram showing the relationship between the dose of the deepest peak and a short circuit capacity improvement rate in a configuration having a plurality of peaks. FIG. 7 shows a simulation result. The dose at the deepest peak is a ratio (%) of the dose contained within ±3σp of the deepest peak to the total dose. σp is a projected dispersion derived from an implantation depth of boron. In this simulation, the total dose was set to 5.4×10¹²/cm², and three levels of the distance from the rear surface 11b to the deepest peak, that is, the depth, were confirmed. The solid line indicates the result at a depth of 0.55 μm, the dashed line indicates the result at a depth of 0.44 μm, and the dash-dotted line indicates the result at a depth of 0.32 μm. The short circuit capacity improvement rate indicates the rate of change in the short circuit capacity relative to a configuration having a single peak at a depth of 0.05 μm. The depth of the collector layer 12 was set to 1 μm.

As shown in FIG. 7, when the dose contained in ±3σp of the deepest peak is set to 13% or more of the total dose, the short circuit capacity can be improved, specifically, improved by 5% or more, regardless of the depth (position) of the deepest peak. In particular, when the dose contained within ±3σp of the deepest peak is 22% or more of the total dose, the short circuit capacity can be further improved, specifically, improved by 10% or more, regardless of the depth (position) of the deepest peak. Moreover, the deeper the deepest peak is located, that is, the closer the deepest peak is to the FS layer 13, the more the short circuit capacity can be improved. For example, when the depth of the deepest peak is 0.55 μm, that is, when the peak position is biased toward the FS layer 13 relative to the center in the depth direction of the collector layer 12, the short circuit capacity can be improved by 10% or more by making the dose 13% or more of the total dose.

In the collector layer 12, the minimum concentration in the region from the rear surface 11b of the semiconductor substrate 11 to the deepest peak is not particularly limited. As an example, in the present embodiment, the minimum concentration from the rear surface 11b to the deepest peak is 1×10¹⁶/cm³ or more. This makes it possible to reduce the turn-off loss as described above while reducing the on-voltage.

FIG. 8 shows the relationship between the on-voltage (Von) and the turn-off loss (Eoff). FIG. 8 shows a simulation result. In this simulation, the depth of the collector layer 12 was set to 1 μm, and two levels of the minimum concentration were confirmed. The solid line indicates the result when the minimum concentration was 1×10¹⁶/cm³, and the solid line indicates the result when the minimum concentration was 1×10¹⁵/cm³.

When the minimum concentration was set to 1×10¹⁶/cm³, the resistance in the current path became smaller than when the minimum concentration was set to 1×10¹⁵/cm³. Therefore, as shown in FIG. 8, it is possible to reduce the turn-off loss while reducing the on-voltage.

The distance L1 from the rear surface 11b to the maximum peak of the FS layer 13 is not particularly limited. In the present embodiment, as an example, the distance L1 is 0.8 μm or more. With this configuration, even if a scratch occurs on the rear surface 11b during the manufacturing process, the scratch is unlikely to reach the FS layer 13. This makes it possible to suppress fluctuations in the breakdown voltage, that is, fluctuations in the characteristics of the semiconductor device 10.

### Second Embodiment

The present embodiment is a modification of the preceding embodiment as a basic configuration and may incorporate description of the preceding embodiment. In the preceding embodiment, the above-described conditions are satisfied over the entire collector layer. Alternatively, the above-described conditions may be satisfied in only a portion of the collector layer.

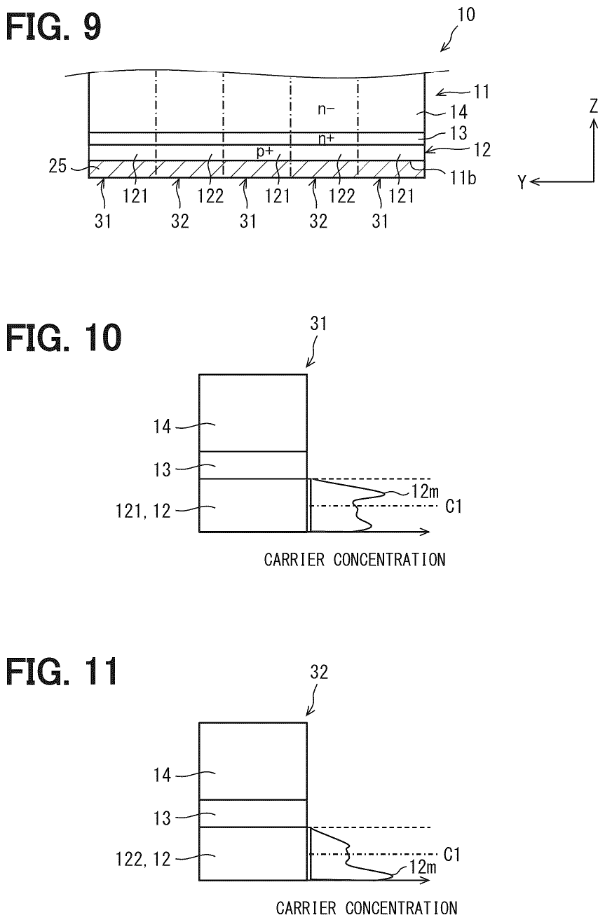

FIG. 9 shows a semiconductor device 10 according to the present embodiment. FIG. 9 corresponds to FIG. 2. FIG. 9 shows a part of the semiconductor device 10 close to the rear surface 11b. FIG. 10 is a diagram showing a first element region. FIG. 11 is a diagram showing a second element region. FIG. 10 and FIG. 11 also show a carrier concentration in the collector layer.

As shown in FIG. 9, FIG. 10, and FIG. 11, the semiconductor substrate 11 includes first element regions 31 and second element regions 32. Some parts of the plurality of cells are the first element regions 31 and other parts of the plurality of cells are the second element regions 32. As in the preceding embodiment, the total dose of the collector layer 12 is less than 1×10¹³/cm².

The first element regions 31 have collector layers 121 as the collector layer 12, the second element regions 32 have collector layers 122 as the collector layer 12, and the collector layers 121 and the collector layers 122 have different configurations. The collector layers 121 of the first element regions 31 satisfy the above-described condition. In other words, the collector layers 121 are provided so that the dose contained within ±3σp of the deepest peak accounts for 13% or more of the total dose. Furthermore, a maximum peak 12m where the carrier concentration in the collector layer 121 is maximum is positioned biased toward the drift layer 14 relative to a center C1 of the collector layer 12 in the depth direction. In other words, the maximum peak 12m is located closer to the FS layer 13 relative to the center C1.

The collector layer 122 of the second element region 32 do not satisfy the above-described condition. That is, in the collector layer 122, the dose contained within ±3σp of the deepest peak is less than 13% of the total dose. Moreover, the maximum peak 12m of the collector layer 122 is positioned biased toward the collector electrode 25 relative to the center C1 of the collector layer 12. In other words, the maximum peak 12m is located closer to the rear surface 11b relative to the center C1.

As an example, in the present embodiment, the first element region 31 and the second element region 32 are arranged alternately. Specifically, the first element region 31 and the second element region 32 are arranged alternately in the Y direction, which is the direction in which the trenches 18 are arranged side by side. The first element region 31 and the second element region 32 are alternately arranged to form stripes.

### <Summary of Second Embodiment>

According to the present embodiment, the semiconductor substrate 11 includes the first element regions 31 and the second element regions 32. The total dose of the collector layer 12 is less than 1×10¹³/cm², and the collector layers 121 of the first element regions 31 are provided so that the dose contained within ±3σp of the deepest peak accounts for 13% or more of the total dose. Therefore, similarly to the configuration shown in the preceding embodiment, it is possible to improve the short circuit capacity and reduce the turn-off loss. In particular, since the maximum peaks 12m are located deeper than the center C1, the short circuit capacity can be improved.

On the other hand, the collector layers 122 of the second element regions 32 do not satisfy the condition for the deepest peak. However, the maximum peaks 12m of the collector layers 122 are located shallower than the center C1. This can improve the ohmic characteristics.

In this manner, the semiconductor device 10 includes the first element regions 31 capable of reducing turn-off loss while improving the short circuit capacity, and the second element regions 32 capable of improving the ohmic characteristics. The first element regions 31 and the second element regions 32 are mixed. Therefore, it is possible to improve the short circuit capacity, reduce the turn-off loss, and ensure the ohmic characteristics.

As an example, in the present embodiment, the first element region 31 and the second element region 32 are arranged alternately. This makes it possible to suppress deviations in characteristics within the surface. For example, it is possible to suppress bias in ohmic contact points.

### Modified Examples

The arrangement of the first element regions 31 and the second element regions 32 is not limited to the above-described example. For example, the width of the second element regions 32 may be set to be equal to or greater than the thickness of the drift layer 14. Specifically, it is preferable that the width of the second element regions 32 is set to 50 μm or more. This can further stabilize the operation of the second element regions 32. The width corresponds to the width of the collector layer. The width is the length of the corresponding collector layer and the length in the arrangement direction of the first element regions 31 and the second element regions 32.

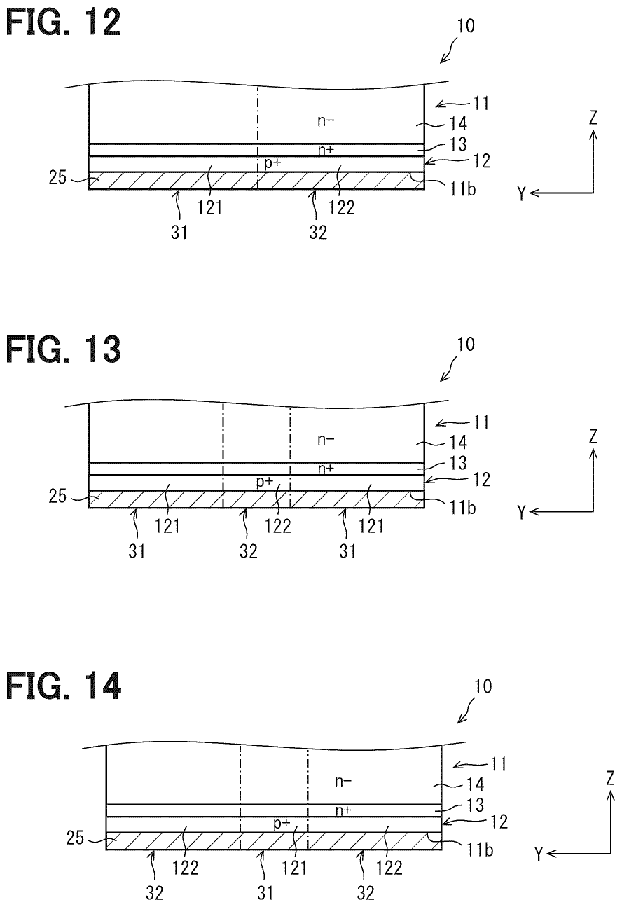

The arrangement of the first element regions 31 and the second element regions 32 is not limited to the alternating arrangement. The semiconductor substrate 11 may include at least one first element region 31 and at least one second element region 32. In an example shown in FIG. 12, the semiconductor substrate 11 includes one first element region 31 and one second element region 32.

The widths of the first element region 31 and the second element region 32 may be equal to each other or different from each other. For example, as shown in FIG. 13, the width of the first element regions 31 may be made wider than the width of the second element region 32. This can improve the short circuit capacity compared to, for example, a configuration in which the widths are equal to each other. As shown in FIG. 14, the width of the second element regions 32 may be made wider than the width of the first element region 31. This can improve the ohmic characteristics, for example, compared to a configuration in which the widths are equal to each other.

The arrangement of the first element region 31 and the second element region 32 is not limited to the stripe shape. For example, the first element region 31 and the second element region 32 may be arranged in a dot pattern.

### Other Embodiments

The disclosure in this specification, the drawings, and the like is not limited to the exemplified embodiments. The disclosure encompasses the illustrated embodiments and modifications by those skilled in the art based thereon. For example, the disclosure is not limited to the combinations of components and/or elements shown in the embodiments. The disclosure may be implemented in various combinations. The disclosure may have additional portions that may be added to the embodiments. The disclosure encompasses omission of components and/or elements of the embodiments. The disclosure encompasses the replacement or combination of components and/or elements between one embodiment and another. The disclosed technical scopes are not limited to the description of the embodiments. It should be understood that a part of disclosed technical scopes are indicated by claims, and the present disclosure further includes modifications within an equivalent scope of the claims.

The disclosure in the specification, the drawings and the like is not limited by the description of the claims. The disclosures in the specification, the drawings, and the like encompass the technical ideas described in the claims, and further extend to a wider variety of technical ideas than those in the claims. Therefore, various technical ideas can be extracted from the disclosure of the specification, the drawings and the like without being limited to the description of the claims.

When an element or a layer is described as “disposed above”, “coupled to” “connected to” or “combined with”, the element or the layer may be directly disposed above, coupled to, connected to, or combined with another element or another layer, or an intervening element or an intervening layer may be present therebetween. In contrast, when an element is described as “directly disposed on,” “directly coupled to,” “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatial relative terms “inside”, “outside”, “rear”, “bottom”, “low”, “top”, “high”, and the like are used herein to facilitate the description that describes relationships between one element or feature and another element or feature. Spatial relative terms can be intended to include different orientations of a device in use or operation, in addition to the orientations illustrated in the drawings. For example, when a device in a drawing is turned over, elements described as “below” or “directly below” other elements or features are oriented “above” the other elements or features. Therefore, the term “below” can include both above and below. The device may be oriented in another direction (rotated 90 degrees or in any other direction) and the spatially relative terms used herein are interpreted accordingly.

Although the IGBT has been shown as one example of the vertical element, the present disclosure is not limited to this example. The vertical element may be an IGBT with a freewheeling diode connected in anti-parallel, that is, an RC-IGBT. RC is an abbreviation for Reverse Conducting.

Although an example of the gate electrodes 20 having the trench structure has been shown, the present disclosure is not limited to this example. The gate electrodes 20 may be disposed on the front surface 11a of the semiconductor substrate 11 via the gate insulating film 19.

Although an example in which n-conductivity type is defined as the first conductivity type and p-conductivity type is defined as the second conductivity type has been shown, the present disclosure is not limited to this example. The first conductivity type may be p-conductivity type and the second conductivity type may be n-conductivity type.

What is claimed is:

1. A semiconductor device comprising:
a drift layer of a first conductivity type;
a base layer of a second conductivity type disposed on the drift layer and providing a front surface of a semiconductor substrate;
an emitter region of the first conductivity type disposed in a surface layer of the base layer close to the front surface;
a gate electrode facing the base layer located between the drift layer and the emitter region through a gate insulating film;
a collector layer of the second conductivity type disposed on an opposite side of the drift layer from the base layer and providing a rear surface of the semiconductor substrate;
a field stop layer of the first conductivity type disposed between the collector layer and the drift layer and having a carrier concentration higher than a carrier concentration of the drift layer;
an emitter electrode disposed on the front surface and electrically connected to the base layer and the emitter region; and
a collector electrode disposed on the rear surface and electrically connected to the collector layer, wherein
the collector layer has a total dose of less than 1×10¹³/cm²,
the collector layer has a plurality of peaks of a carrier concentration, and
at least a portion of the collector layer is configured to satisfy a condition that a dose contained within ±3σp of a deepest peak, which is a peak at a deepest position relative to the rear surface among the plurality of peaks, accounts for 13% or more of the total dose.

2. The semiconductor device according to claim 1, wherein
a distance from the rear surface to a maximum peak at which the carrier concentration in the field stop layer is maximum is 0.8 μm or more.

3. The semiconductor device according to claim 1, wherein a minimum carrier concentration from the rear surface to the deepest peak is 1×10¹⁶/cm³ or more.

4. The semiconductor device according to claim 1, wherein
the semiconductor substrate includes:
a first element region in which the collector layer satisfies the condition, and a maximum peak in which the carrier concentration in the collector layer is maximum is positioned biased toward the drift layer relative to a center of the collector layer; and
a second element region in which the collector layer does not satisfy the condition and the maximum peak is positioned biased toward the collector electrode relative to the center of the collector layer.

5. The semiconductor device according to claim 4, wherein
the first element region and the second element region are arranged alternately.
